(19) United States
(12) Patent Application Publication
(10) Pub. No.: US 2026/0165103 A1
(43) Pub. Date: Jun. 11, 2026

(54) METHOD FOR SELF-ALIGNED VIA FORMATION IN A SEMICONDUCTOR DEVICE

(71) Applicant: Tokyo Electron Limited, Tokyo (JP)

(72) Inventors: Ying TRICKETT, Albany, NY (US); Hirokazu AIZAWA, Albany, NY (US)

(73) Assignee: Tokyo Electron Limited, Tokyo (JP)

(21) Appl. No.: 18/929,144

(22) Filed: Oct. 28, 2024

(51) Int. Cl. H01L 21/768; H01L 21/033; H01L 21/3213

(52) U.S. Cl. CPC H10W 20/081; H10P 50/71; H10P 76/4085; H10W 20/056; H10W 20/063; H10W 20/098

(57) ABSTRACT

The technique herein addresses the lithography overlay challenge caused by aggressive scaling and possible adoption of subtractive interconnect formation. The self-aligned vias can be fabricated on top of metal lines by apply two strategies. First, the removal of a hard mask after interlayer dielectric (ILD) chemical mechanical polishing (CMP) provides a starting self-aligned template. Second, the addition of sidewall spacers on metal lines facilitates self-aligned features promoted by excellent etch selectivity and spatial confinement.

### FIELD OF THE INVENTION

The present disclosure relates to microelectronic devices including semiconductor devices, transistors, and integrated circuits, and methods of microfabrication.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

In the manufacture of a semiconductor device, for example especially on the micro- or nanoscopic scale, various fabrication processes are executed such as film-forming depositions, etch mask creation, patterning, material etching and removal, and doping treatments. These processes are performed repeatedly to form desired semiconductor device elements on a substrate. With microfabrication, transistors have been created in one plane with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

Notably, any lithography overlay issue becomes a contributing factor to yield loss as scaling continues, and a subtractive integration scheme makes the via to metal line overlay tolerance even tighter. Thus, a method to mitigate overlay constraints, especially when aligned to scaled interconnects, is desired.

### SUMMARY

The present disclosure relates to a method of forming vias, including forming a multilayer stack on a substrate, the multilayer stack including an interconnect layer disposed overtop the substrate and a hard mask disposed overtop the interconnect layer; forming a first interconnect and a second interconnect from the interconnect layer by applying a subtractive etch; forming spacers on sidewalls of the first interconnect, the second interconnect, and the hard mask; forming a first dielectric layer around the first interconnect and the second interconnect and flush with a top of the hard mask; removing the hard mask; forming an etch stop layer overtop the first dielectric layer, the spacers, the first interconnect, and the second interconnect; forming a second dielectric layer overtop the etch stop layer; forming a resist pattern overtop the second dielectric layer, uncovered regions in the resist pattern configured to define an underlying via pattern; etching the uncovered regions in the resist pattern to form the via pattern, the etch stop layer preventing the etching from removing the first dielectric layer disposed between the first interconnect and the second interconnect; removing uncovered portions of the etch stop layer; and depositing a metal in the formed via pattern.

In an embodiment, a first uncovered region of the uncovered regions is disposed overtop and offset from a center of the first interconnect.

In an embodiment, the first uncovered region is offset from the center of the first interconnect and between the first interconnect and the second interconnect.

In an embodiment, the method further includes forming a mask layer overtop the second dielectric layer before forming the resist pattern.

In an embodiment, the mask layer includes an organic dielectric layer (ODL) disposed overtop the etch stop layer.

In an embodiment, the mask layer includes a low-temperature oxide (LTO) disposed overtop the ODL and a bottom anti-reflective coating (BARC) disposed overtop the LTO.

In an embodiment, the ODL and the BARC are formed via a spin-on coating.

In an embodiment, the LTO is formed via chemical vapor deposition.

In an embodiment, the mask layer includes a silicon-containing BARC (Si-ARC) disposed overtop the LTO.

In an embodiment, the Si-ARC is formed via a spin-on coating.

In an embodiment, the method further including removing the resist pattern and the mask layer before the depositing the metal in the formed via.

In an embodiment, the forming the first dielectric layer around the first interconnect and the second interconnect further comprises depositing the first dielectric layer overtop the first interconnect and the second interconnect; and removing portions of the first dielectric layer by applying a chemical mechanical polish until the hard mask is reached.

In an embodiment, the forming the spacers on the sidewalls of the first interconnect, the second interconnect, and the hard mask further comprises performing a selective deposition of the spacers selective to metal surfaces; and etching back the spacers to be flush with tops of the hard mask.

In an embodiment, the forming the spacers on the sidewalls of the first interconnect, the second interconnect, and the hard mask further comprises performing a non-selective deposition of the spacers; and performing an anisotropic etch.

In an embodiment, a material of the first interconnect and the second interconnect is ruthenium.

In an embodiment, a material of the first metal is ruthenium.

In an embodiment, a width of the first interconnect is less than 25 nm.

In an embodiment, a material of the hard mask is a metal hard mask including TiN, WC (carbon-doped tungsten), WO (tungsten oxide) or ZrO.

In an embodiment, a material of the etch stop layer is at least one selected from the group consisting of SiCN, SiN, SiC, Al2O3, SiOCN, and SiOC.

In an embodiment, a material of the spacer is at least one selected from the group consisting of SiN, SiO2, Al2O3 and graphene.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIG. 1A is a schematic of vias formed under aligned conditions.

FIG. 1B is a schematic of vias formed under misaligned conditions, according to an embodiment of the present disclosure.

FIG. 2A is a schematic of a cross-section of a starting multilayer stack for subtractive interconnect formation, according to an embodiment of the present disclosure.

FIG. 2B is a schematic of a cross-section of the multilayer stack after an etch of the subtractive interconnect formation method, according to an embodiment of the present disclosure.

FIG. 2C is a schematic of a cross-section of the device after spacer formation, according to an embodiment of the present disclosure.

FIG. 2D is a schematic of a cross-section of the device after dielectric fill, according to an embodiment of the present disclosure.

FIG. 2E is a schematic of a cross-section of the device after a CMP, according to an embodiment of the present disclosure.

FIG. 2F is a schematic of a cross-section of the device after removing the hard mask, according to an embodiment of the present disclosure.

FIG. 2G is a schematic of a cross-section of the device after formation of an etch stop layer, according to an embodiment of the present disclosure.

FIG. 2H is a schematic of a cross-section of the device after dielectric fill, according to an embodiment of the present disclosure.

FIG. 2I is a schematic of a cross-section of the device after resist patterning, according to an embodiment of the present disclosure.

FIG. 2J is a schematic of a cross-section of the device after etching, according to an embodiment of the present disclosure.

FIG. 2K is a schematic of a cross-section of the device after removal of the etch stop layer, according to an embodiment of the present disclosure.

FIG. 2L is a schematic of a cross-section of the device after formation of the first metal, according to an embodiment of the present disclosure.

FIG. 3A is a schematic of a cross-section of the device after resist patterning, according to an embodiment of the present disclosure.

FIG. 3B is a schematic of a cross-section of the device after a misaligned etching, according to an embodiment of the present disclosure.

FIG. 3C is a schematic of a cross-section of the device after removal of the etch stop layer, according to an embodiment of the present disclosure.

FIG. 3D is a schematic of a cross-section of the device after formation of the first metal, according to an embodiment of the present disclosure.

FIG. 4A is a schematic of a cross-section of the device with the increased distanced between the misaligned via and the adjacent (left) interconnect, according to an embodiment of the present disclosure.

FIG. 4B is a schematic of a cross-section of a device formed without the etch stop layer and the misaligned resist pattern, according to an embodiment of the present disclosure.

FIG. 5 is a flow chart for a method of self-aligned via formation, according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

As described herein, a self-aligned via (SAV) formation method is described that can mitigate overlay constraint, especially when aligned to scaled interconnects. The addition of sidewall spacers on a patterned metal line can provide further etch stop and confinement for the SAV formation.

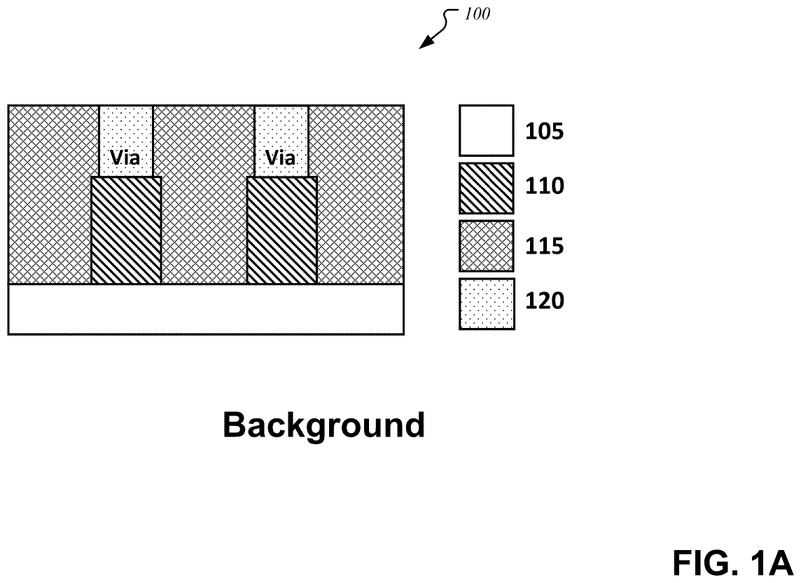

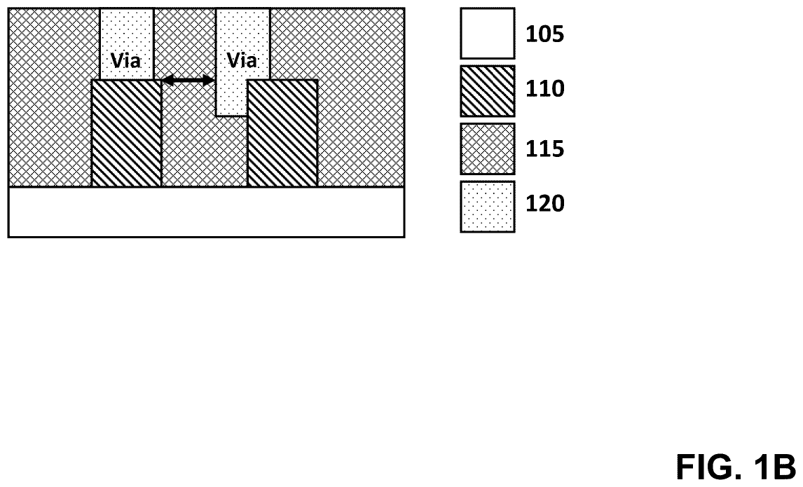

FIG. 1A is a schematic of vias formed under aligned conditions. In an embodiment, a semiconductor device 100 includes a substrate 105, interconnects 110, a first dielectric 115, and a first metal 120. A material of the substrate 105 can be, for example, silicon. The interconnects 110 can be, for example, metal lines or power rails. A material of the interconnects 110 can be, for example, ruthenium. A material of the first metal 120 can be, for example, ruthenium. As shown, the two vias have been formed substantially aligned overtop the interconnects 110, which generally does not present a high risk of shorting between the interconnects 110.

FIG. 1B is a schematic of vias formed under misaligned conditions, according to an embodiment of the present disclosure. In an embodiment, misalignment of a photoresist pattern for defining the vias can result in a misaligned via formed offset from a center of an interconnect. As shown, a misaligned via formed over the right interconnect of the interconnects 110 is not aligned with the right interconnect of the interconnects 110 and the misaligned via is formed into the first dielectric 115 disposed between the interconnects 110. Thus, the first metal 120 filled in the misaligned via is disposed a shorter distance from a left interconnect of the interconnects 110, which can result in a short, especially over time in the context of time-dependent dielectric breakdown (TDDB). That is, when compared to the aligned vias (and the interconnects 110) of FIG. 1A, the device 100 of FIG. 1B can have a higher short potential between one of the interconnects 110 and the misaligned via, especially as the device 100 ages.

The proposed method herein addresses the lithography overlay challenge caused by aggressive scaling and possible adoption of subtractive interconnect formation. The SAV can be fabricated on top of metal lines by apply two strategies. First, the removal of a hard mask after interlayer dielectric (ILD) chemical mechanical polishing (CMP) provides a starting self-aligned template. Second, the addition of sidewall spacers on metal lines facilitates self-aligned features promoted by excellent etch selectivity and spatial confinement.

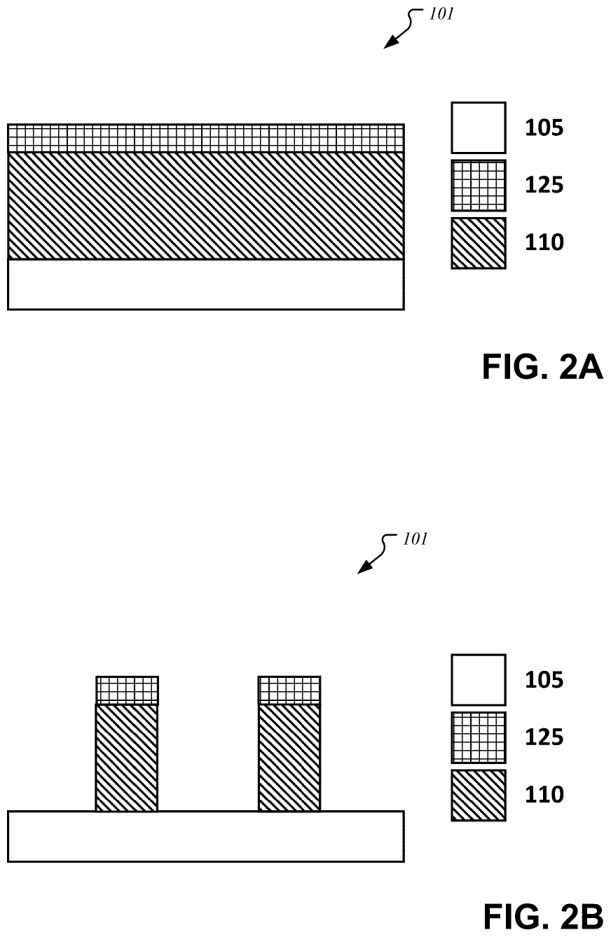

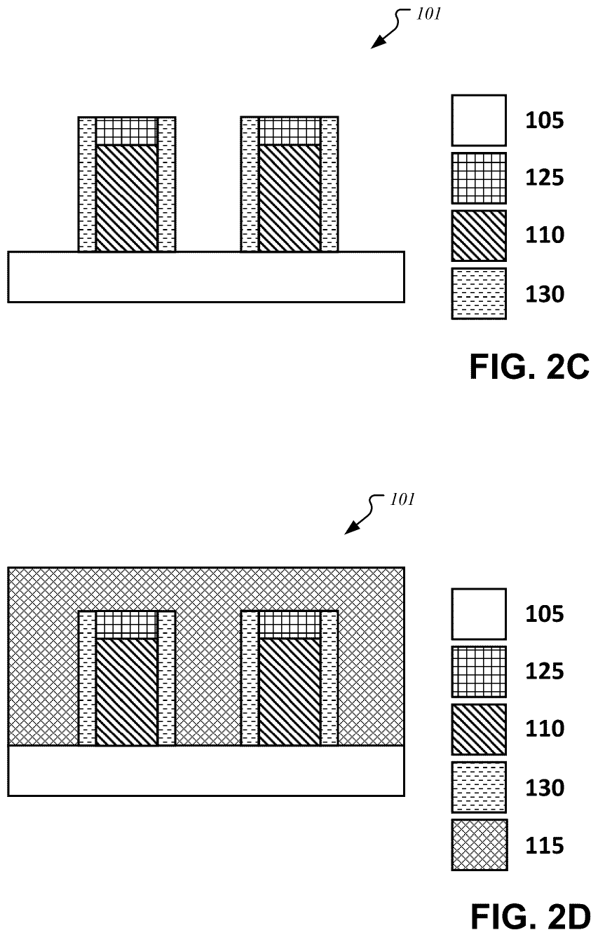

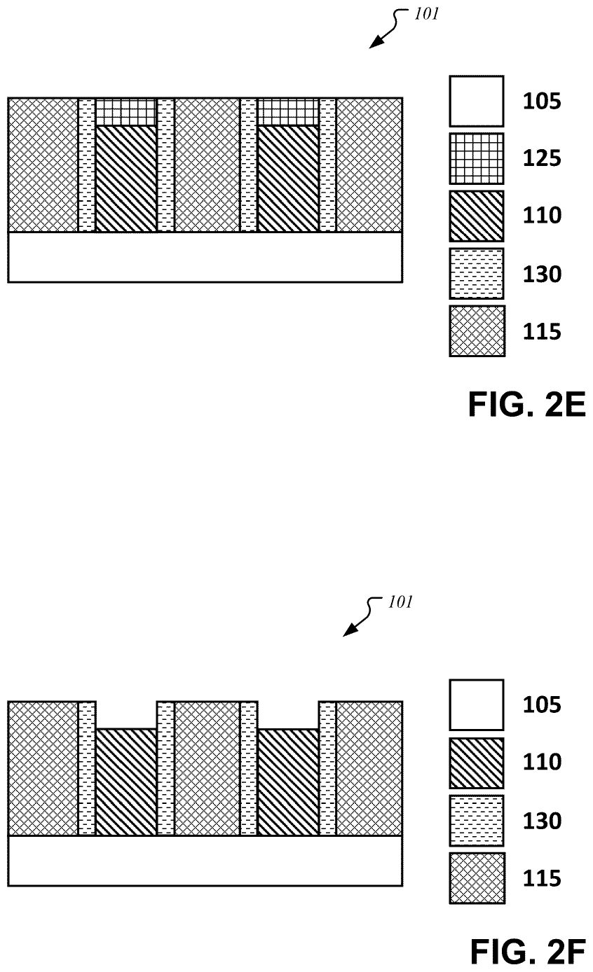

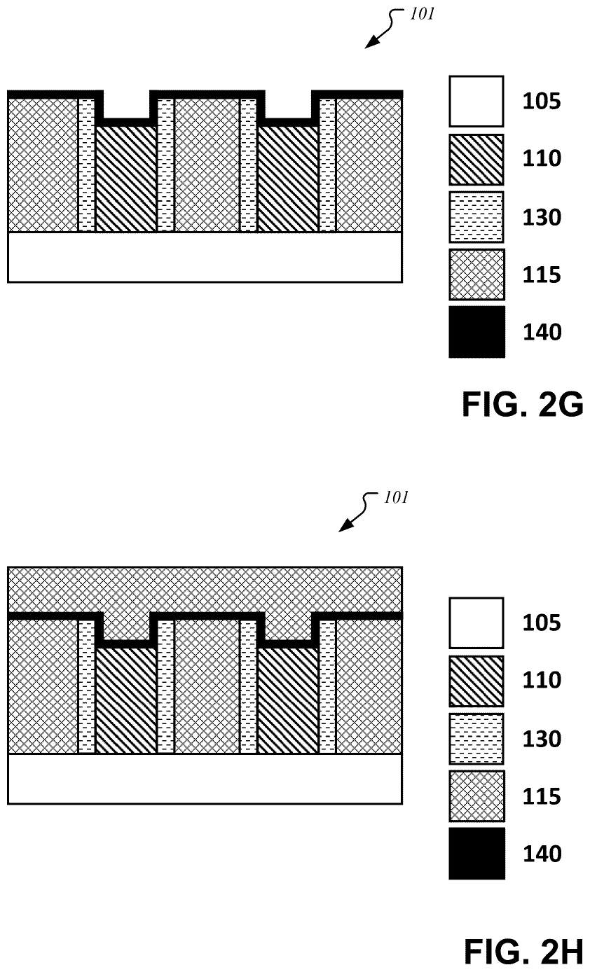

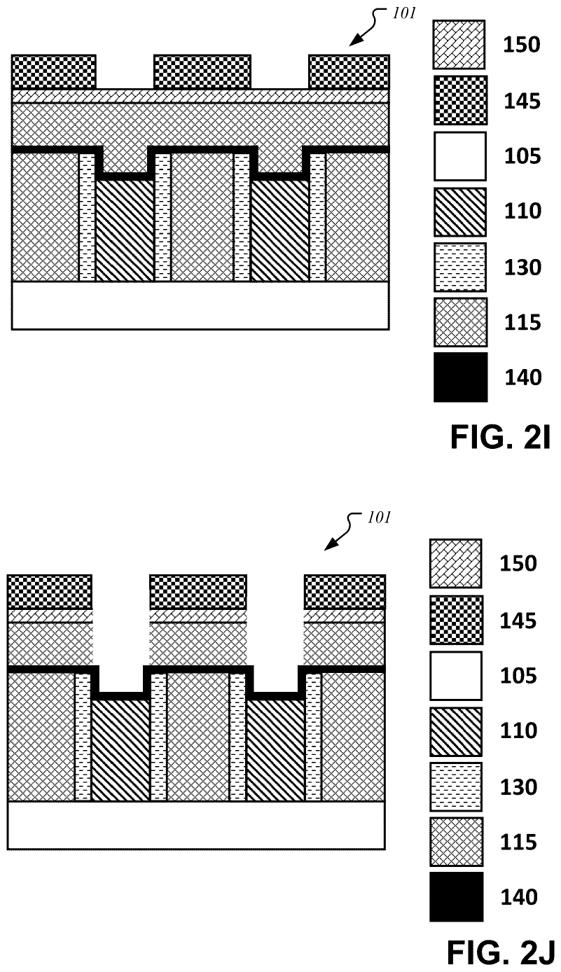

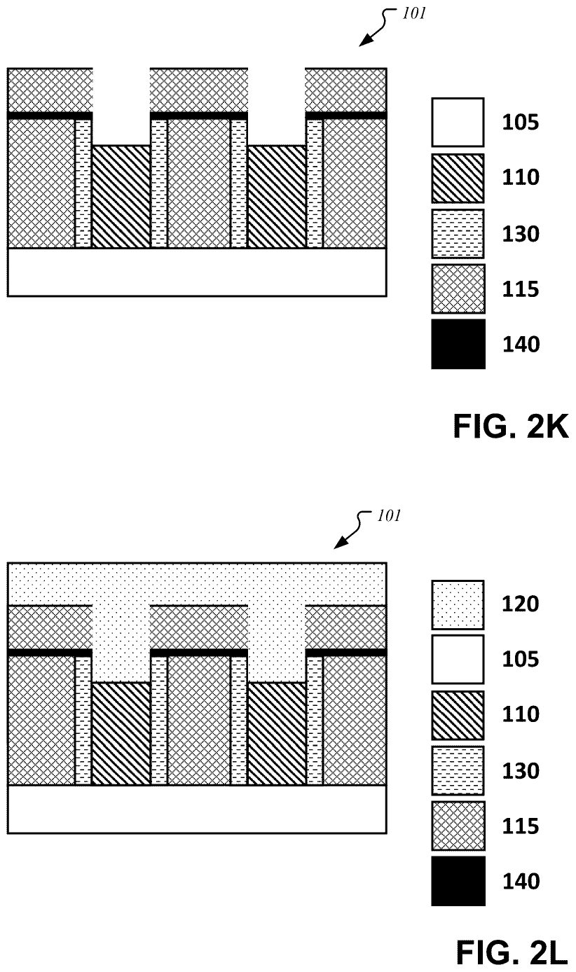

To this end, FIG. 2A is a schematic of a cross-section of a starting multilayer stack for subtractive interconnect formation, according to an embodiment of the present disclosure. In an embodiment, a semiconductor device 101, similar to the device 100, includes a multilayer stack of the substrate 105, the interconnects 110, and a hard mask 125. The interconnects 110 layer can be formed overtop the substrate 105, and the hard mask 125 can be formed overtop the interconnects 110. A material of the hard mask 125 can be a metal hard mask, for example, TiN, WC (carbon-doped tungsten), WO (tungsten oxide), or ZrO among others. The hard mask 125 can be a metal hard mask to have selective deposition of the spacer 130 on the sidewall of the hard mask 125 and the interconnects 110 together.

FIG. 2B is a schematic of a cross-section of the multilayer stack after an etch of the subtractive interconnect formation method, according to an embodiment of the present disclosure. In an embodiment, the device 101 can be patterned and etched to define and form the interconnects 110 with the hard mask 125 disposed overtop.

FIG. 2C is a schematic of a cross-section of the device 101 after spacer formation, according to an embodiment of the present disclosure. In an embodiment, spacers 130 can be formed on sidewalls of the interconnects 110. The spacers 130 can be formed by, for example, selective deposition on metal surfaces or by blanket deposition followed by anisotropic etching. In an embodiment, the spacers 130 can be recessed or etched back down to be flush with tops of the hard mask 125. A material of the spacers 130 can be, for example, SiN, SiO2, Al2O3, or graphene, among others. Notably, the sidewall spacers 130 can provide further etch stop and confinement for the SAV formation.

FIG. 2D is a schematic of a cross-section of the device 101 after dielectric fill, according to an embodiment of the present disclosure. In an embodiment, a first dielectric 115 can be formed to fill around the interconnects 110, the hard mask 125, and the spacers 130 (an ILD deposition or gap fill). A material of the first dielectric 115 can be, for example, SiO2 or other low-k material, among others.

FIG. 2E is a schematic of a cross-section of the device 101 after a CMP, according to an embodiment of the present disclosure. In an embodiment, an excess of the first dielectric 115 can be removed via the CMP to uncover the hard mask 125 and the spacers 130. Notably, the hard mask 125 can act as a polishing stopper for the CMP process.

FIG. 2F is a schematic of a cross-section of the device 101 after removing the hard mask 125, according to an embodiment of the present disclosure. In an embodiment, an etch can be performed to remove the hard mask 125 from overtop the interconnects 110. The etch can be, for example, a selective wet etch.

FIG. 2G is a schematic of a cross-section of the device 101 after formation of an etch stop layer 140, according to an embodiment of the present disclosure. In an embodiment, the etch stop layer 140 can be deposited overtop the interconnects 110, the first dielectric 115, and the spacers 130. A material of the etch stop layer 140 can be, for example, SiCN, Al2O3, SiN, or SiC, among others.

FIG. 2H is a schematic of a cross-section of the device 101 after dielectric fill, according to an embodiment of the present disclosure. In an embodiment, the first dielectric 115 can be formed to fill around the etch stop layer 140, and another CMP process can be performed to level or planarize the first dielectric 115.

FIG. 2I is a schematic of a cross-section of the device 101 after resist patterning, according to an embodiment of the present disclosure. In an embodiment, a mask layer 150 can be formed overtop the planarized first dielectric 115. The mask layer 150 can include multiple layers.

In an embodiment, the mask layer 150 can include, for example, a bottom anti-reflective coating (BARC) as an upper layer (farther from the substrate 105), a low-temperature oxide (LTO) middle layer, and an organic dielectric layer (ODL) as a lower layer (closer to the substrate 105). The BARC can be formed by, for example, a spin-on deposition. The LTO can be formed by, for example, a chemical vapor deposition (CVD) process. A material of the LTO can be, for example, SiO2. The ODL can be formed by, for example, a spin-on deposition.

In an embodiment, the mask layer 150 can include, for example, a silicon-containing BARC (Si-ARC) as an upper layer and the ODL as a lower layer. The Si-ARC can be formed by, for example, a spin-on deposition. A material of the Si-ARC can be, for example, SiO2. The ODL can be formed by, for example, a spin-on deposition.

In an embodiment, a resist pattern 145 can be formed overtop the first dielectric 115 and the mask layer 150. The resist pattern 145 can be configured to define the subsequent vias during via formation.

FIG. 2J is a schematic of a cross-section of the device 101 after etching, according to an embodiment of the present disclosure. In an embodiment, an etch can be performed to form the vias. As previously described, the formation of the vias can be guided by the resist pattern 145. Notably, substantially vertical sidewalls are shown for simplicity, but the sidewalls resulting from the etch can be sloped due to the etch being isotropic. The depth of the etch, and thus the depth of the vias, can be stopped by (and defined by) the etch stop layer 140. This can be advantageous when the resist pattern 145 is not aligned properly with the interconnects 110 and the subsequent etching to form the vias is also misaligned since the etch stop layer 140 can prevent unwanted etching into the first dielectric 115 in between the neighboring interconnects 110.

FIG. 2K is a schematic of a cross-section of the device 101 after removal of the etch stop layer 140, according to an embodiment of the present disclosure. In an embodiment, the mask layer 150 and the resist pattern 145 can be removed from overtop the first dielectric 115, and the etch stop layer 140 can be removed where uncovered by the etching to form the vias.

FIG. 2L is a schematic of a cross-section of the device 101 after formation of the first metal 120, according to an embodiment of the present disclosure. In an embodiment, the first metal 120 can be deposited to fill the vias and contact the interconnects 110. A CMP can also be performed to planarize the interconnects 110 disposed overtop the first dielectric 115 and the interconnects 110. A material of the first metal 120 can be, for example, ruthenium, among others.

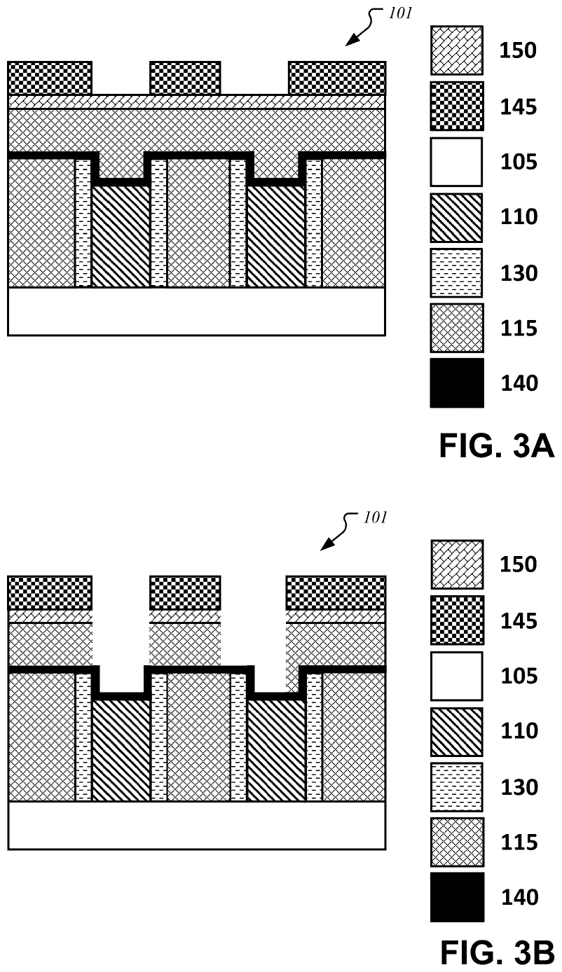

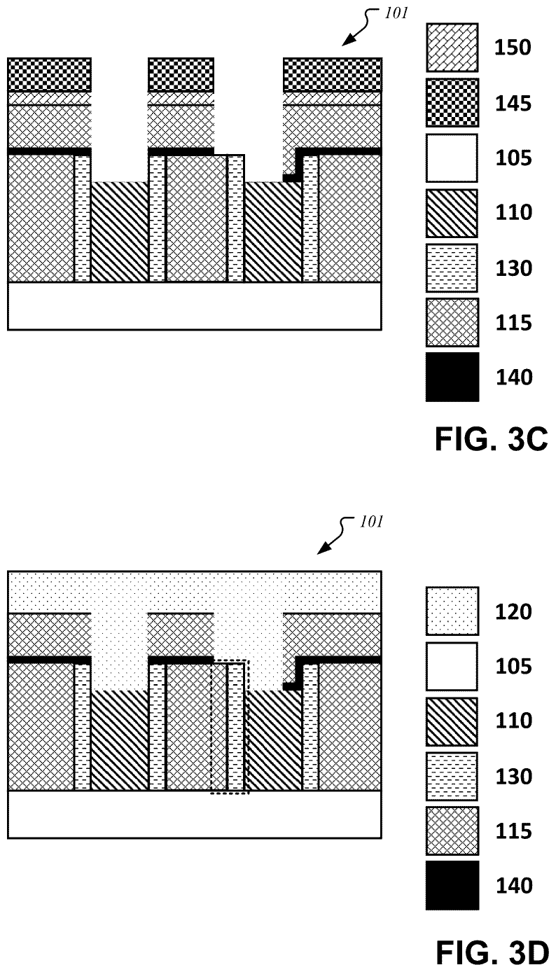

Described above and shown in FIGS. 2A to 2L is a substantially aligned via formation. To provide an illustrative example, a misaligned via formation is described herein with reference to FIGS. 3A to 3D. The same or similar steps can be applied from FIGS. 2A to 2H. Thus, FIG. 3A commences the subtractive interconnect formation and device formation thereafter.

To this end, FIG. 3A is a schematic of a cross-section of the device 101 after resist patterning, according to an embodiment of the present disclosure. In an embodiment, the mask layer 150 can be formed overtop the planarized first dielectric 115 and the resist pattern 145 can be formed overtop the first dielectric 115 and the mask layer 150. As previously described, the resist pattern 145 can be configured to define the subsequent vias during via formation, and notably, the resist pattern 145 shown in FIG. 3A can be misaligned (e.g., as compared to FIG. 2I). The opening in the resist pattern 145 on the right can be offset from a center of the right interconnect. This can lead to a misaligned etch.

FIG. 3B is a schematic of a cross-section of the device 101 after a misaligned etching, according to an embodiment of the present disclosure. In an embodiment, since the resist pattern 145 is offset, the etch can result in formation of a via overtop the right interconnect that is offset from the center of the right interconnect. However, as previously described, the etch stop layer 140 can advantageously still stop any etch progress. Thus, the etch does not remove any material of the first dielectric 115 from in between the interconnects 110 and thus does not form a via into the region in between the interconnects 110 that will subsequently be filled with conductive material. Therefore, the etch stop layer 140 protects a corner of the first dielectric 115 disposed in between the interconnects 110, which will later prevent a corner of the filled first metal 120 in the via from causing an increased risk of shorting due to the closer distance to the adjacent interconnect.

FIG. 3C is a schematic of a cross-section of the device 101 after removal of the etch stop layer 140, according to an embodiment of the present disclosure. In an embodiment, the mask layer 150 and the resist pattern 145 can be removed from overtop the first dielectric 115, and the etch stop layer 140 can be removed where uncovered by the etching to form the vias.

FIG. 3D is a schematic of a cross-section of the device 101 after formation of the first metal 120, according to an embodiment of the present disclosure. In an embodiment, the first metal 120 can be deposited to fill the vias and contact the interconnects 110. A CMP can also be performed to planarize the interconnects 110 disposed overtop the first dielectric 115 and the interconnects 110. Notably, as indicated by the dashed box, the etch stop layer 140 can prevent the unwanted etching of the material in the dashed box when the etch stop layer 140 is not included in the method of forming the vias. The addition of the sidewall spacers 130 on the patterned interconnects 110 can provide further etch stop and confinement for SAV formation.

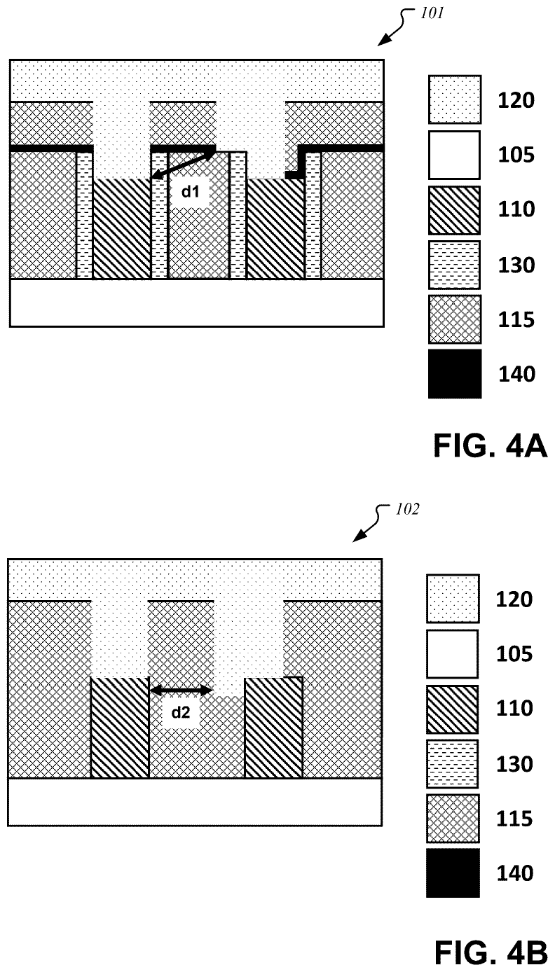

FIG. 4A is a schematic of a cross-section of the device 101 with the increased distanced between the misaligned via and the adjacent (left) interconnect, according to an embodiment of the present disclosure. In an embodiment, the distance “d1” can represent the distance between the nearest material of the first metal 120 on the right and the interconnect on the left. The distance d1 can lead to shorting issues when the distance is too short, especially as the device device 101 ages.

FIG. 4B is a schematic of a cross-section of a device 102 formed without the etch stop layer 140 and the misaligned resist pattern 145, according to an embodiment of the present disclosure. In an embodiment, the etch after the misaligned resist pattern 145 can progress into the first dielectric 115 in between the interconnects 110 without the etch stop layer 140 and the first metal 120 filled in the via thereafter can be a distance “d2” away from the left interconnect. Therefore, since the etch was able to proceed into the region in between the interconnects 110, the distance d2 is less than the distance d1 and the risk of a short for the device 102 is greater than the risk of a short for the device 101.

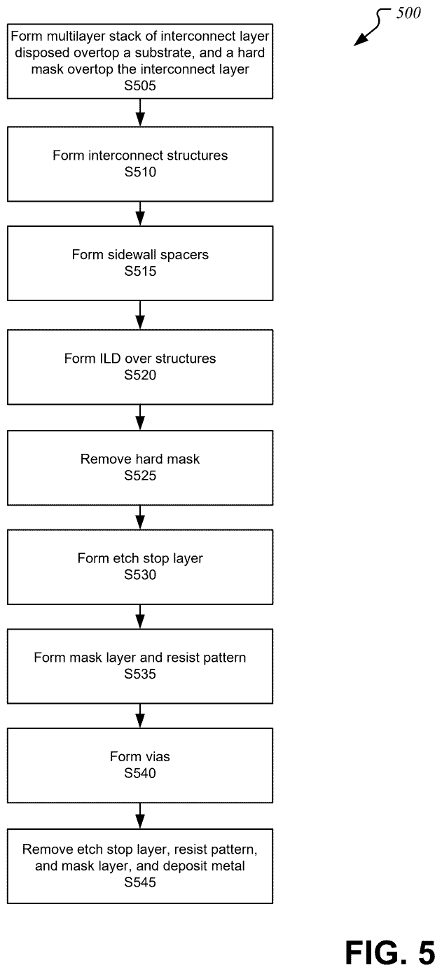

FIG. 5 is a flow chart for a method 500 of self-aligned via formation, according to an embodiment of the present disclosure. In an embodiment, at step S505, a multilayer stack can be formed on the substrate 105, the multilayer stack including the interconnects 110 layer disposed overtop the substrate 105, and the hard mask 125 disposed overtop the interconnects 110 layer.

In an embodiment, at step S510, the individual interconnects 110 can be formed via subtractive interconnect formation.

In an embodiment, at step S515, the sidewall spacers 130 can be formed on sidewalls of the interconnects 110. The spacers 130 can be formed by, for example, selective deposition on metal surfaces.

In an embodiment, at step S520, the first dielectric 115 can be deposited over the interconnects 110.

In an embodiment, at step S525, the hard mask 125 can be removed from overtop the interconnects 110.

In an embodiment, at step S530, the etch stop layer 140 can be formed overtop the interconnects 110, the spacers 130, and the first dielectric 115.

In an embodiment, at step S535, the mask layer 150 can be formed overtop the first dielectric 115, and the resist pattern 145 can be formed overtop the mask layer 150.

In an embodiment, at step S540, the vias can be formed. For example, a selective wet etch can remove the first dielectric 115 material to form the vias.

In an embodiment, at step S545, the etch stop layer 140, the resist pattern 145, and the mask layer 150 can be removed, and the first metal 120 can be deposited in the formed vias.

Notably, the method described above can be used with various metals for the interconnects 110 and the first metal 120. As previously stated, ruthenium can be the metal of choice. Copper can be a metal used as well, but a resistivity of the copper can increase in small feature sizes, whereas a resistivity of ruthenium does not increase as much as copper. Thus, for small feature sizes, such as 20 nm pitches, ruthenium resistivity can be smaller than copper resistivity. That is, a width of the interconnects 110 can be, for example, less than 30 nm, or less than 25 nm, or 20 nm. Also, copper can be more difficult to subtractively etch as compared to ruthenium. Thus, for a multilayer device, the device can include ruthenium in the very small vertical connections, and then the larger layers above and below can include copper still.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Embodiments of the present disclosure may also be as set forth in the following parentheticals.
(1) A method of forming vias, including forming a multilayer stack on a substrate, the multilayer stack including an interconnect layer disposed overtop the substrate and a hard mask disposed overtop the interconnect layer; forming a first interconnect and a second interconnect from the interconnect layer by applying a subtractive etch; forming spacers on sidewalls of the first interconnect, the second interconnect, and the hard mask; forming a first dielectric layer around the first interconnect and the second interconnect and flush with a top of the hard mask; removing the hard mask; forming an etch stop layer overtop the first dielectric layer, the spacers, the first interconnect, and the second interconnect; forming a second dielectric layer overtop the etch stop layer; forming a resist pattern overtop the second dielectric layer, uncovered regions in the resist pattern configured to define an underlying via pattern; etching the uncovered regions in the resist pattern to form the via pattern, the etch stop layer preventing the etching from removing the first dielectric layer disposed between the first interconnect and the second interconnect; removing uncovered portions of the etch stop layer; and depositing a metal in the formed via pattern.
(2) The method of (1), wherein a first uncovered region of the uncovered regions is disposed overtop and offset from a center of the first interconnect.
(3) The method of either (1) or (2), wherein the first uncovered region is offset from the center of the first interconnect and between the first interconnect and the second interconnect.
(4) The method of any one of (1) to (3), further comprising: forming a mask layer overtop the second dielectric layer before forming the resist pattern.
(5) The method of any one of (1) to (4), wherein the mask layer includes an organic dielectric layer (ODL) disposed overtop the etch stop layer.
(6) The method of any one of (1) to (5), wherein the mask layer includes a low-temperature oxide (LTO) disposed overtop the ODL and a bottom anti-reflective coating (BARC) disposed overtop the LTO.
(7) The method of any one of (1) to (6), wherein the ODL and the BARC are formed via a spin-on coating.
(8) The method of any one of (1) to (7), wherein the LTO is formed via chemical vapor deposition.
(9) The method of any one of (1) to (8), wherein the mask layer includes a silicon-containing BARC (Si-ARC) disposed overtop the LTO.
(10) The method of any one of (1) to (9), wherein the Si-ARC is formed via a spin-on coating.
(11) The method of any one of (1) to (10), further comprising: removing the resist pattern and the mask layer before the depositing the metal in the formed via.

(12) The method of any one of (1) to (11), wherein the forming the first dielectric layer around the first interconnect and the second interconnect further comprises depositing the first dielectric layer overtop the first interconnect and the second interconnect; and removing portions of the first dielectric layer by applying a chemical mechanical polish until the hard mask is reached.
(13) The method of any one of (1) to (12), wherein the forming the spacers on the sidewalls of the first interconnect, the second interconnect, and the hard mask further comprises performing a selective deposition of the spacers selective to metal surfaces; and etching back the spacers to be flush with tops of the hard mask.
(14) The method of any one of (1) to (13), wherein the forming the spacers on the sidewalls of the first interconnect, the second interconnect, and the hard mask further comprises performing a non-selective deposition of the spacers; and performing an anisotropic etch.
(15) The method of any one of (1) to (14), wherein a material of the first interconnect and the second interconnect is ruthenium.
(16) The method of any one of (1) to (15), wherein a material of the first metal is ruthenium.
(17) The method of any one of (1) to (16), wherein a width of the first interconnect is less than 25 nm.
(18) The method of any one of (1) to (17), wherein a material of the hard mask is a metal hard mask including TiN, WC (carbon-doped tungsten), WO (tungsten oxide) or ZrO.
(19) The method of any one of (1) to (18), wherein a material of the etch stop layer is at least one selected from the group consisting of SiCN, SiN, SiC, Al2O3, SiOCN, and SiOC.
(20) The method of any one of (1) to (19), wherein a material of the spacer is at least one selected from the group consisting of SiN, SiO2, Al2O3, and graphene.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of forming vias, the method comprising:
forming a multilayer stack on a substrate, the multilayer stack including an interconnect layer disposed overtop the substrate and a hard mask disposed overtop the interconnect layer;
forming a first interconnect and a second interconnect from the interconnect layer by applying a subtractive etch;
forming spacers on sidewalls of the first interconnect, the second interconnect, and the hard mask;
forming a first dielectric layer around the first interconnect and the second interconnect and flush with a top of the hard mask;
removing the hard mask;
forming an etch stop layer overtop the first dielectric layer, the spacers, the first interconnect, and the second interconnect;
forming a second dielectric layer overtop the etch stop layer;
forming a resist pattern overtop the second dielectric layer, uncovered regions in the resist pattern configured to define an underlying via pattern;
etching the uncovered regions in the resist pattern to form the via pattern, the etch stop layer preventing the etching from removing the first dielectric layer disposed between the first interconnect and the second interconnect;
removing uncovered portions of the etch stop layer; and
depositing a metal in the formed via pattern.

2. The method of claim 1, wherein a first uncovered region of the uncovered regions is disposed overtop and offset from a center of the first interconnect.

3. The method of claim 2, wherein the first uncovered region is offset from the center of the first interconnect and between the first interconnect and the second interconnect.

4. The method of claim 1, further comprising:
forming a mask layer overtop the second dielectric layer before forming the resist pattern.

5. The method of claim 4, wherein the mask layer includes an organic dielectric layer (ODL) disposed overtop the etch stop layer.

6. The method of claim 5, wherein the mask layer includes a low-temperature oxide (LTO) disposed overtop the ODL and a bottom anti-reflective coating (BARC) disposed overtop the LTO.

7. The method of claim 6, wherein the ODL and the BARC are formed via a spin-on coating.

8. The method of claim 6, wherein the LTO is formed via chemical vapor deposition.

9. The method of claim 5, wherein the mask layer includes a silicon-containing BARC (Si-ARC) disposed overtop the LTO.

10. The method of claim 9, wherein the Si-ARC is formed via a spin-on coating.

11. The method of claim 4, further comprising:
removing the resist pattern and the mask layer before the depositing the metal in the formed via.

12. The method of claim 1, wherein the forming the first dielectric layer around the first interconnect and the second interconnect further comprises
depositing the first dielectric layer overtop the first interconnect and the second interconnect; and
removing portions of the first dielectric layer by applying a chemical mechanical polish until the hard mask is reached.

13. The method of claim 1, wherein the forming the spacers on the sidewalls of the first interconnect, the second interconnect, and the hard mask further comprises
performing a selective deposition of the spacers selective to metal surfaces; and
etching back the spacers to be flush with tops of the hard mask.

14. The method of claim 1, wherein the forming the spacers on the sidewalls of the first interconnect, the second interconnect, and the hard mask further comprises
performing a non-selective deposition of the spacers; and
performing an anisotropic etch.

15. The method of claim 1, wherein a material of the first interconnect and the second interconnect is ruthenium.

16. The method of claim 1, wherein a material of the first metal is ruthenium.

17. The method of claim 16, wherein a width of the first interconnect is less than 25 nm.

18. The method of claim 1, wherein a material of the hard mask is at least one selected from the group consisting of TiN, WC, WO, and ZrO.

19. The method of claim 1, wherein a material of the etch stop layer is at least one selected from the group consisting of SiCN, SiN, SiC, Al2O3, SiOCN, and SiOC.

20. The method of claim 1, wherein a material of the spacer is at least one selected from the group consisting of SiN, SiO2, Al2O3, and graphene.
